(19) United States
(12) Patent Application Publication
(10) Pub. No.: US 2026/0053069 A1
(43) Pub. Date: Feb. 19, 2026

(54) SEMICONDUCTOR PACKAGE

(71) Applicant: SAMSUNG ELECTRONICS CO., LTD., Suwon-si (KR)

(72) Inventors: Yeonwook Jung, Suwon-si (KR); Kwanghoe Heo, Suwon-si (KR)

(21) Appl. No.: 19/224,670

(22) Filed: May 30, 2025

(30) Foreign Application Priority Data
Aug. 16, 2024 (KR) 10-2024-0109995

(51) Int. Cl. H01L 25/16; H01L 23/31

(52) U.S. Cl. CPC H01L 25/16; H01L 23/3107; H01L 2225/06506; H01L 2225/0651; H01L 2225/06562

(57) ABSTRACT

The present disclosure relates to a semiconductor package. A semiconductor package according to implementations of the present disclosure includes a package substrate and a chip stack including semiconductor chips sequentially stacked on the package substrate. Each of the semiconductor chips includes a first side surface provided on one side of a virtual central line perpendicular to an upper surface of the package substrate and passing through a center of the chip stack and also a second side surface provided on the other side of the virtual central line. Odd-numbered semiconductor chips among the stacked semiconductor chips include heat source circuits adjacent to the first side surfaces, and even-numbered semiconductor chips among the stacked semiconductor chips include heat source circuits adjacent to the second side surfaces.

### CROSS-REFERENCE TO RELATED APPLICATION(S)

This application claims priority under 35 U.S.C. § 119 to Korean Patent Application No. 10-2024-0109995 filed on Aug. 16, 2024, in the Korean Intellectual Property Office, the disclosures of which are incorporated by reference herein in their entireties.

### BACKGROUND

Implementations of the present disclosure described herein relate to a semiconductor package.

Recently, a semiconductor package including a plurality of stacked semiconductor chips has been variously researched to cope with a high speed and multifunctionalization of electronic products. However, when the semiconductor package is operated, heat may be generated from the stacked semiconductor chips and accumulated in the semiconductor package. The accumulated heat may degrade performance of the semiconductor package.

### SUMMARY

Implementations of the present disclosure provide a semiconductor package that may reduce or minimize accumulation of heat.

According to some implementations, a semiconductor package includes a package substrate and a chip stack on the package substrate, wherein the chip stack comprises a plurality of semiconductor chips, wherein each semiconductor chip of the plurality of semiconductor chips includes a first side surface provided on one side of a virtual central line perpendicular to an upper surface of the package substrate and passing through a center of the chip stack and a second side surface provided on the other side of the virtual central line, odd-numbered semiconductor chips among the plurality of semiconductor chips include heat source circuits adjacent to the first side surfaces, and even-numbered semiconductor chips among the plurality of semiconductor chips include heat source circuits adjacent to the second side surfaces.

According to some implementations, a semiconductor package includes a package substrate, a lower chip stack on the package substrate, the lower chip stack comprising a first plurality of semiconductor chips, and an upper chip stack on the lower stack, the upper chip stack comprising a second plurality of semiconductor chips, wherein each semiconductor chip of the lower stack and the upper stack includes a first side surface provided on one side of a virtual central line perpendicular to an upper surface of the package substrate and passing through a center of the respective chip stack in which the semiconductor chip is positioned and a second side surface provided on the other side of the virtual central line, wherein the second plurality of semiconductor chips of the upper chip stack include heat source circuits adjacent to the first side surfaces, and wherein the first plurality of semiconductor chips of the lower chip stack include heat source circuits adjacent to the second side surfaces.

According to some implementations, a semiconductor package includes a package substrate, a chip stack on the package substrate, wherein the chip stack includes a plurality of semiconductor chips, and a logic chip on the package substrate and including heat source circuits electrically connected to the plurality of semiconductor chips of the chip stack.

### BRIEF DESCRIPTION OF THE FIGURES

The above and other objects and features of the present disclosure will become apparent by describing in detail implementations thereof with reference to the accompanying drawings.

FIG. 1 is a cross-sectional view illustrating a semiconductor package according to some implementations of the present disclosure.

FIG. 2 is a cross-sectional view illustrating the semiconductor package according to some implementations of the present disclosure.

FIG. 3 is a cross-sectional view illustrating the semiconductor package according to some implementations of the present disclosure.

FIG. 4 is a plan view illustrating semiconductor chips according to some implementations of the present disclosure.

FIG. 5 is a cross-sectional view illustrating the semiconductor package according to some implementations of the present disclosure.

FIG. 6 is a plan view illustrating the semiconductor chips according to some implementations of the present disclosure.

FIG. 7 is a plan view illustrating the semiconductor chips according to some implementations of the present disclosure.

FIG. 8 is a cross-sectional view illustrating the semiconductor package according to some implementations of the present disclosure.

FIGS. 9A and 9B are cross-sectional views illustrating the semiconductor packages according to some implementations of the present disclosure.

FIG. 10 is a plan view illustrating the semiconductor chips according to some implementations of the present disclosure.

### DETAILED DESCRIPTION

Hereinafter, implementations of the present disclosure will be described clearly and in detail with reference to the accompanying drawings.

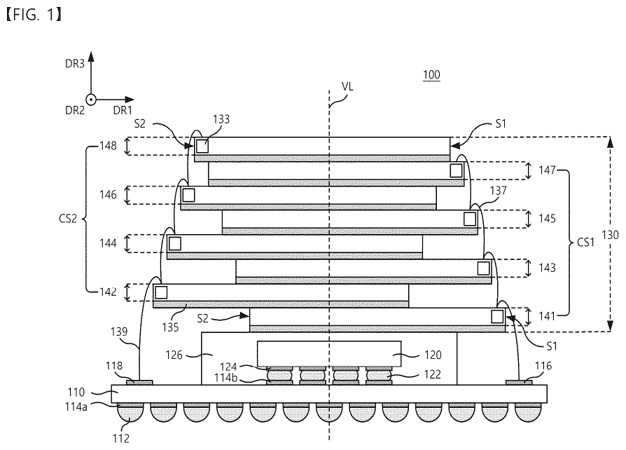

FIG. 1 is a cross-sectional view illustrating a semiconductor package according to some implementations of the present disclosure.

Referring to FIG. 1, a semiconductor package 100 may include a package substrate 110, a base chip 120, and a chip stack 130.

In some implementations, the semiconductor package 100 may be applied to various types of electronic devices such as desktop computers, tablet computers, laptop computers, smartphones, wearable devices, digital cameras, display devices, workstations, servers, electric vehicles, home appliances (televisions and set-top boxes), and medical devices.

The base chip 120 and the chip stack 130 may be arranged on the package substrate 110 and may be electrically connected to the package substrate 110. That is, the package substrate 110 may transmit signals generated from the base chip 120 and the chip stack 130 to an external device and transmit signals and power from the external device to the base chip 120 and the chip stack 130.

In some implementations, the package substrate 110 may include lower substrate pads 114a, upper substrate pads 114b, a first substrate pad 116, and a second substrate pad 118. The lower substrate pads 114a may be provided on a lower surface of the package substrate 110, and the upper substrate pads 114b, the first substrate pad 116, and the second substrate pad 118 may be provided on an upper surface of the package substrate 110. The lower substrate pads 114a, the upper substrate pads 114b, the first substrate pad 116, and the second substrate pad 118 may be electrically connected to each other through internal wiring lines provided in the package substrate 110 to satisfy a design of the semiconductor package 100.

External terminals 112 may be provided on lower surfaces of the lower substrate pads 114a, respectively. The external terminals 112 may be connected to the external device. In other words, the semiconductor package 100 may receive the signals and the power from the external device through the external terminals 112 and transmit the signals of the base chip 120 and the chip stack 130 to the external device through the external terminals 112. For example, each of the external terminals 112 may be a solder ball or a solder bump.

The base chip 120 may include connection pads 124 on a lower surface thereof. The base chip 120 may be mounted on the upper surface of the package substrate 110. Here, the connection pads 124 of the base chip 120 may face the upper surface of the package substrate 110. In some implementations, the base chip 120 may be mounted on the upper substrate pads 114b. The connection pads 124 may be electrically connected to the upper substrate pads 114b. In some implementations, an internal terminal 122 may be provided between the connection pads 124 and the upper substrate pads 114b. In other words, each of the connection pads 124 may be electrically connected to a corresponding one of the upper substrate pads 114b through the internal terminal 122. For example, the internal terminal 122 may be a solder ball or a solder bump.

As described above, the first substrate pad 116 and the second substrate pad 118 may be arranged on the upper surface of the package substrate 110. In some implementations, the first substrate pad 116 may be provided as a plurality of first substrate pads 116, and the second substrate pad 118 may be also provided as a plurality of second substrate pads 118. In some implementations, the first substrate pad 116 and the second substrate pad 118 may be arranged on an edge of the upper surface of the package substrate 110. However, implementations of the present disclosure are not limited thereto. In some implementations, the first substrate pads 116 and the second substrate pads 118 may be provided at different locations.

The chip stack 130 may be provided on the base chip 120. In other words, the base chip 120 may be disposed between the chip stack 130 and the package substrate 110. The base chip 120 may control semiconductor chips 141 to 148 included in the chip stack 130. In other words, the base chip 120 may be a micro-controller (or a micro-processor) for driving or controlling the semiconductor package 100.

In some implementations, the base chip 120 may be covered by an encapsulant 126. In this case, the chip stack 130 may be provided on the encapsulant 126. That is, a portion of the encapsulant 126 may be provided between the chip stack 130 and the base chip 120. In some implementations, the encapsulant 126 may fill a space between the base chip 120 and the package substrate 110. For example, the encapsulant 126 may be formed of an epoxy molding compound (EMC), but the present disclosure is not limited thereto.

The chip stack 130 may be a stacked structure including the plurality of stacked semiconductor chips 141 to 148. Each of the semiconductor chips 141 to 148 may be a semiconductor integrated circuit chip including a plurality of transistors, a capacitor, an inductor, a resistor, and the like. For example, each of the semiconductor chips 141 to 148 may be a memory chip. For example, each of the semiconductor chips 141 to 148 may be a volatile memory chip such as a dynamic random access memory (DRAM) chip or a static random access memory (SRAM) chip or a nonvolatile memory chip such as a NAND flash memory chip, a phase-change random access memory (PRAM) chip, a magnetic random access memory (MRAM) chip, a ferroelectric random access memory (FeRAM) chip, or a resistive random access memory (RRAM) chip.

In contrast, at least one of the semiconductor chips 141 to 148 may be a microprocessor such as a central processing unit (CPU), a graphics processing unit (GPU), or an application processor (AP), an analog element, or a digital signal processor.

The semiconductor chips 141 to 148 may be stacked in a third direction DR3. In some implementations, the semiconductor chips 141 to 148 may be the same type of semiconductor chips. In some implementations, each of the semiconductor chips 141 to 148 may include a heat source circuit 133. Here, the heat source circuit 133 may be defined as a circuit that generates relatively high heat inside the semiconductor chips 141 to 148 during operation. In some implementations, the stacked semiconductor chips 141 to 148 of the chip stack 130 may be classified into odd-numbered semiconductor chips CS1 and even-numbered semiconductor chips CS2. For example, the odd-numbered semiconductor chips CS1 may include the first semiconductor chip 141, the third semiconductor chip 143, the fifth semiconductor chip 145, and the seventh semiconductor chip 147, and the even-numbered semiconductor chips CS2 may include the second semiconductor chip 142, the fourth semiconductor chip 144, the sixth semiconductor chip 146, and the eighth semiconductor chip 148. For convenience of description, it is disclosed that the chip stack 130 includes the first to eighth semiconductor chips 141 to 148. However, implementations of the present disclosure are not limited thereto. The number of semiconductor chips of the chip stack 130 may be variously changed.

In some implementations, the semiconductor chips 141 to 148 of the chip stack 130 may have first side surfaces S1 arranged on one side of a virtual central line VL and second side surfaces S2 arranged on the other side of the virtual central line VL. Here, the virtual central line VL may be a virtual line perpendicular to the upper surface of the package substrate 110 and passing through a center of the chip stack 130. Each of the odd-numbered semiconductor chips CS1 may include the heat source circuit 133 adjacent to the first side surface S1 thereof, and each of the even-numbered semiconductor chips CS2 may include the heat source circuit 133 adjacent to the second side surface S2 thereof.

Each of the even-numbered semiconductor chips CS2 and the odd-numbered semiconductor chips CS1 immediately therebelow may be point-symmetrically arranged on a plane. For example, the second semiconductor chip 142 and the first semiconductor chip 141 may be arranged point-symmetrically with respect to the center of the chip stack 130 on a plane.

In some implementations, each of the stacked semiconductor chips 141 to 148 may include a first end including the first side surface S1 and a second end including the second side surface S2. Like the first side surfaces S1 and the second side surfaces S2, the first ends of the semiconductor chips 141 to 148 may be arranged on one side of the virtual central line VL, and the second ends of the semiconductor chips 141 to 148 may be arranged on the other side of the virtual central line VL. The first ends of the odd-numbered semiconductor chips CS1 may include the heat source circuits 133, respectively, and the second ends of the even-numbered semiconductor chips CS2 may include the heat source circuits 133, respectively. Meanwhile, the second ends of the odd-numbered semiconductor chips CS1 may not include the heat source circuits 133, and the first ends of the even-numbered semiconductor chips CS2 may not include the heat source circuits 133.

In some implementations, the first ends of the even-numbered semiconductor chips CS2 may be laterally offset from the first ends of the odd-numbered semiconductor chips CS1. Further, the second ends of the odd-numbered semiconductor chips CS1 may be laterally offset from the second ends of the even-numbered semiconductor chips CS2.

In some implementations, as illustrated in FIG. 1, the first ends of the odd-numbered semiconductor chips CS1 may be arranged in the form of uphill steps (e.g., a tiered structure) toward the virtual central line VL. Further, the second ends of the even-numbered semiconductor chips CS2 may be arranged in the form of uphill steps (e.g., a tiered structure) toward the virtual central line VL.

In some implementations, the semiconductor chips 141 to 148 may be stacked using adhesive layers 135. In more detail, the adhesive layer 135 may be provided on a lower surface of each of the semiconductor chips 141 to 148, and the semiconductor chips 141 to 148 may adhere to each other by the adhesive layers 135. A lowermost one (i.e., the first semiconductor chip 141) of the semiconductor chips 141 to 148 may adhere to the encapsulant 126 through the adhesive layer 135. However, implementations of the present disclosure are not limited thereto. In some implementations, the encapsulant 126 may be omitted, and the adhesive layer 135 on the lower surface of the first semiconductor chip 141 may directly adhere to an upper surface of the base chip 120.

In some implementations, each of the semiconductor chips 141 to 148 may include a chip pad disposed on an upper surface thereof. For example, the chip pads of the odd-numbered semiconductor chips CS1 may be arranged on upper surfaces of the first ends of the odd-numbered semiconductor chips CS1, and the chip pads of the even-numbered semiconductor chips CS2 may be arranged on upper surfaces of the second ends of the even-numbered semiconductor chips CS2.

In some implementations, the odd-numbered semiconductor chips CS1 and the package substrate 110 may be electrically connected to each other through first conductive wires 137. For example, the first conductive wires 137 may be connected to the chip pads of the odd-numbered semiconductor chips CS1 and the first substrate pad(s) 116 of the package substrate 110. The even-numbered semiconductor chips CS2 and the package substrate 110 may be electrically connected to each other through second conductive wires 139. For example, the second conductive wires 139 may be connected to the chip pads of the even-numbered semiconductor chips CS2 and the second substrate pad(s) 118 of the package substrate 110. However, implementations of the present disclosure are not limited thereto. In some implementations, the semiconductor chips 141 to 148 may be connected to each other through through-electrodes passing through the semiconductor chips 141 to 148.

As described above, in the semiconductor package 100 according to some implementations of the present disclosure, heat accumulation may be reduced or minimized by vertically and alternately arranging the heat source circuits 133 of the semiconductor chips 141 to 148.

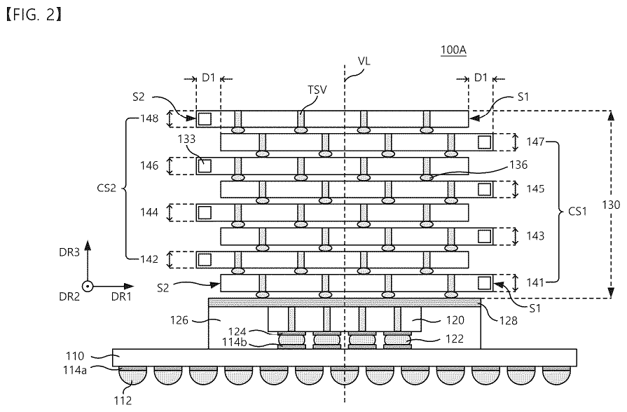

FIG. 2 is a cross-sectional view illustrating the semiconductor package according to some implementations of the present disclosure. Hereinafter, for convenience of description, differences from the above-described implementations will be mainly described.

Referring to FIG. 2, a semiconductor package 100A may include through-electrodes TSV and chip terminals 136. In more detail, the through-electrodes TSV may pass through the semiconductor chips 141 to 148 in the third direction DR3 and may provide electrical paths connecting the semiconductor chips 141 to 148. For example, the through-electrodes TSV may be through-silicon vias. The chip terminals 136 may be provided on lower surfaces of the through-electrodes TSV, respectively. Each of the chip terminals 136 may be connected to a corresponding one of the chip pads of the semiconductor chip located immediately therebelow. For example, each of the chip terminals 136 may be a solder ball or a solder bump.

When the semiconductor chips 141 to 148 are connected to each other using the through-electrodes TSV and the chip terminals 136, a rewiring layer 128 may be provided on the upper surface of the base chip 120, and the base chip 120 may also include the through-electrodes TSV. The through-electrodes TSV of the base chip 120 may electrically connect the rewiring layer 128 to the connection pads 124. The chip terminals 136 on the lower surfaces of the through-electrodes TSV of the first semiconductor chip 141 (i.e., a lowermost semiconductor chip) may be electrically connected to the rewiring layer 128. That is, the semiconductor chips 141 to 148 may be electrically connected to the base chip 120 through the rewiring layer 128. In this case, the encapsulant 126 may not cover the upper surface of the base chip 120. For example, an upper surface of the encapsulant 126 may be substantially coplanar with the upper surface of the base chip 120, and the rewiring layer 128 may be provided on the upper surface of the encapsulant 126 and the upper surface of the base chip 120.

In some implementations, the first ends of the even-numbered semiconductor chips CS2 arranged on the one side of the virtual central line VL may be offset from the first ends of the odd-numbered semiconductor chips CS1 arranged on the one side of the virtual central line VL. Here, the first ends of the odd-numbered semiconductor chips CS1 may overlap each other vertically (i.e., in the third direction DR3). Further, the second ends of the odd-numbered semiconductor chips CS1 arranged on the other side of the virtual central line VL may be laterally offset from the second ends of the even-numbered semiconductor chips CS2 arranged on the other side of the virtual central line VL, and the second ends of the even-numbered semiconductor chips CS2 may overlap each other vertically (i.e., in the third direction DR3).

In other words, in the semiconductor package 100A, the first side surfaces S1 of the even-numbered semiconductor chips CS2 may be laterally offset from the first side surfaces S1 of the odd-numbered semiconductor chips CS1 by substantially the same distance (i.e., a first distance D1). Accordingly, the second side surfaces S2 of the odd-numbered semiconductor chips CS1 may also be laterally offset from the second side surfaces S2 of the even-numbered semiconductor chips CS2 by the first distance D1.

Meanwhile, the first conductive wires 137 and the second conductive wires 139 of FIG. 1 may be applied to the semiconductor package 100A. In this case, the through-electrodes TSV, the chip terminals 136, and the rewiring layer 128 may be omitted.

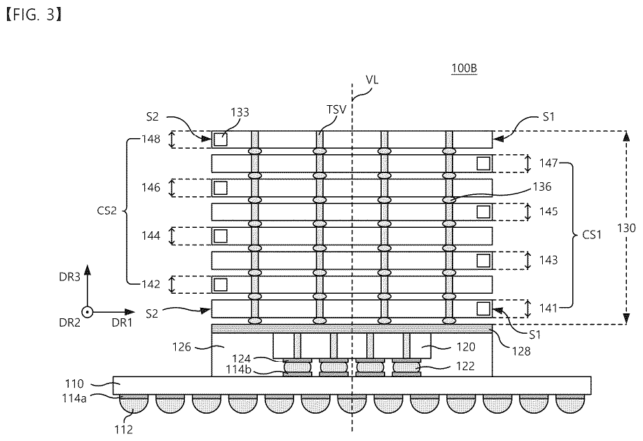

FIG. 3 is a cross-sectional view illustrating a semiconductor package according to some implementations of the present disclosure.

Referring to FIG. 3, in a semiconductor package 100B, the first ends of the semiconductor chips 141 to 148 may vertically overlap each other, and the second ends of the semiconductor chips 141 to 148 may vertically overlap each other. In other words, the first side surfaces S1 of the semiconductor chips 141 to 148 may be vertically aligned with each other, and the second side surfaces S2 of the semiconductor chips 141 to 148 may be vertically aligned with each other.

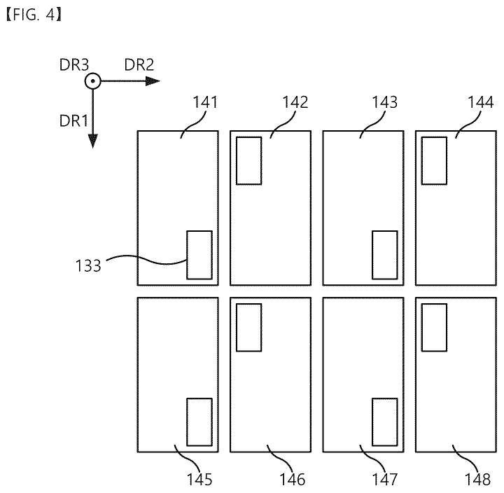

FIG. 4 is a plan view illustrating semiconductor chips according to some implementations of the present disclosure. In detail, FIG. 4 is a plan view illustrating upper surfaces of the semiconductor chips 141 to 148 before stacking.

Referring to FIG. 4, the semiconductor chips 141 to 148 may be the same type of semiconductor chips, and each of the semiconductor chips 141 to 148 may include the heat source circuit 133.

In some implementations, as illustrated in FIG. 4, each of the odd-numbered semiconductor chips (e.g., the first semiconductor chip 141, the third semiconductor chip 143, the fifth semiconductor chip 145, and the seventh semiconductor chip 147) may include the heat source circuit 133 provided inside a corner area in which a lower side and a right side meet each other. In contrast, each of the even-numbered semiconductor chips (e.g., the second semiconductor chip 142, the fourth semiconductor chip 144, the sixth semiconductor chip 146, and the eighth semiconductor chip 148) may include the heat source circuit 133 provided inside a corner area in which a left side and an upper side meet each other. That is, the second semiconductor chip 142, the fourth semiconductor chip 144, the sixth semiconductor chip 146, and the eighth semiconductor chip 148 and the first semiconductor chip 141, the third semiconductor chip 143, the fifth semiconductor chip 145, and the seventh semiconductor chip 147 may be arranged point-symmetrically. It is described in the present implementations that the heat source circuit 133 is provided inside the one corner area of each of the semiconductor chips 141 to 148, but this is merely exemplary, and the present disclosure is not limited thereto.

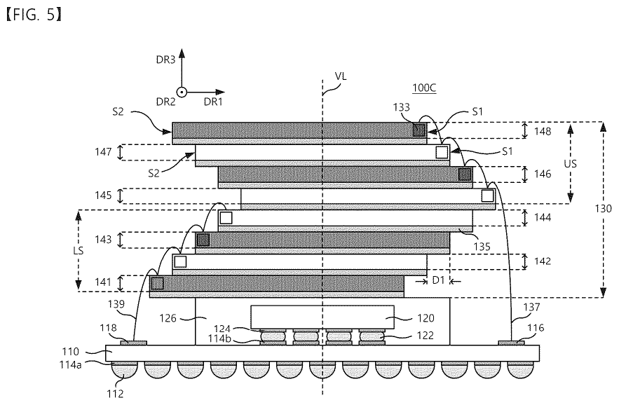

FIG. 5 is a cross-sectional view illustrating the semiconductor package according to some implementations of the present disclosure.

Referring to FIG. 5, a semiconductor package 100C may include N types of different semiconductor chips (here N is a natural number of 2 or more). Hereinafter, the N types of semiconductor chips will be described by an example of a first type of semiconductor chips and a second type of semiconductor chips, but this is merely exemplary, and the present disclosure is not limited thereto.

The N types of semiconductor chips may include the first type of semiconductor chips and the second type of semiconductor chips. In more detail, e ach of the first type of semiconductor chips and the second type of semiconductor chips may include the heat source circuit 133. The heat source circuit 133 of each of the first type of semiconductor chips may be provided in one of a first corner area and a second corner area. Further, the heat source circuit 133 of each of the second type of semiconductor chips may be provided in the other one of the first corner area and the second corner area.

In other words, the heat source circuits 133 of the first type of semiconductor chips may be provided at first positions of the first type of semiconductor chips, and the heat source circuits 133 of the second type of semiconductor chips may be provided at second positions of the second type of semiconductor chips. For example, the first corner area, the second corner area, the third corner area, and the fourth corner area of each of the first type of semiconductor chips may respectively correspond to the first corner area, the second corner area, the third corner area, and the fourth corner area of each of the second type of semiconductor chips, the first position may be one of the first corner area, the second corner area, the third corner area, and the fourth corner area, and the second position may be another one of the first corner area, the second corner area, the third corner area, and the fourth corner area.

In the semiconductor package 100C, a lower stack LS may be provided on the base chip 120, and an upper stack US may be provided on the lower stack LS. The lower stack LS may include the semiconductor chips 141 to 144 sequentially stacked on the base chip 120, and the upper stack US may include the semiconductor chips 145 to 148 sequentially stacked on the lower stack LS. The lower stack LS and the upper stack US may constitute the chip stack 130. For example, the lower stack LS may include the first semiconductor chip 141, the second semiconductor chip 142, the third semiconductor chip 143, and the fourth semiconductor chip 144, and the upper stack US may include the fifth semiconductor chip 145, the sixth semiconductor chip 146, the seventh semiconductor chip 147, and the eighth semiconductor chip 148.

The first semiconductor chip 141, the second semiconductor chip 142, the third semiconductor chip 143, and the fourth semiconductor chip 144 of the lower stack LS may include the first type of semiconductor chips and the second type of semiconductor chips. Here, the odd-numbered semiconductor chips (i.e., the first semiconductor chip 141 and the third semiconductor chip 143) of the lower stack LS may be the first type of semiconductor chips, and the even-numbered semiconductor chips (i.e., the second semiconductor chip 142 and the fourth semiconductor chip 144) of the lower stack LS may be the second type of semiconductor chips.

Each of the semiconductor chips 141 to 148 of the lower stack LS and the upper stack US may have the first side surface S1 disposed on the one side of the virtual central line VL and the second side surface S2 disposed on the other side of the virtual central line VL. Further, each of the semiconductor chips 141 to 148 of the lower stack LS and the upper stack US may include the first end having the first side surface S1 and the second end having the second side surface S2. The first ends of the semiconductor chips 141 to 148 may be arranged on the one side of the virtual central line VL, and the second ends of the semiconductor chips 141 to 148 may be arranged on the other side of the virtual central line VL. The semiconductor chips 141 to 144 of the lower stack LS may include the heat source circuits 133 adjacent to the second side surfaces S2. In more detail, the heat source circuits 133 of the semiconductor chips 141 to 144 of the lower stack LS may be provided inside the second ends of the semiconductor chips 141 to 144 of the lower stack LS.

The second side surfaces S2 of the first semiconductor chip 141, the second semiconductor chip 142, the third semiconductor chip 143, and the fourth semiconductor chip 144 of the lower stack LS may be laterally offset from each other. In more detail, the second ends of the first semiconductor chip 141, the second semiconductor chip 142, the third semiconductor chip 143, and the fourth semiconductor chip 144 of the lower stack LS may be laterally offset from each other. In other words, the second ends of the first semiconductor chip 141, the second semiconductor chip 142, the third semiconductor chip 143, and the fourth semiconductor chip 144 of the lower stack LS may not vertically overlap each other. For example, the second ends of the second semiconductor chip 142, the third semiconductor chip 143, and the fourth semiconductor chip 144 may be laterally offset from the second end of the semiconductor chip immediately therebelow toward the virtual central line VL. For example, the second ends of the first semiconductor chip 141, the second semiconductor chip 142, the third semiconductor chip 143, and the fourth semiconductor chip 144 of the lower stack LS may be arranged in the form of uphill steps (e.g., a tiered structure) toward the virtual central line VL. In other words, the second side surfaces S2 of the first semiconductor chip 141, the second semiconductor chip 142, the third semiconductor chip 143, and the fourth semiconductor chip 144 of the lower stack LS may be sequentially shifted at the same interval in a first direction DR1. As a result, the heat source circuits 133 of the semiconductor chips 141 to 144 of the lower stack LS may not vertically overlap each other.

In some implementations, the fifth semiconductor chip 145, the sixth semiconductor chip 146, the seventh semiconductor chip 147, and the eighth semiconductor chip 148 of the upper stack US may include the first type of semiconductor chips and the second type of semiconductor chips. The even-numbered semiconductor chips (i.e., the sixth semiconductor chip 146 and the eighth semiconductor chip 148) of the upper stack US may be the first type of semiconductor chips, and the odd-numbered semiconductor chips (i.e., the fifth semiconductor chip 145 and the seventh semiconductor chip 147) of the upper stack US may be the second type of semiconductor chips.

The semiconductor chips 145 to 148 of the upper stack US may include the heat source circuits 133 adjacent to the first side surfaces S1. In more detail, the heat source circuits 133 of the semiconductor chips 145 to 148 of the upper stack US may be provided inside the first ends of the semiconductor chips 145 to 148 of the upper stack US.

The first side surfaces S1 of the fifth semiconductor chip 145, the sixth semiconductor chip 146, the seventh semiconductor chip 147, and the eighth semiconductor chip 148 of the upper stack US may be laterally offset from each other. In more detail, the first ends of the fifth semiconductor chip 145, the sixth semiconductor chip 146, the seventh semiconductor chip 147, and the eighth semiconductor chip 148 of the upper stack US may be laterally offset from each other. In other words, the first ends of the fifth semiconductor chip 145, the sixth semiconductor chip 146, the seventh semiconductor chip 147, and the eighth semiconductor chip 148 of the upper stack US may not vertically overlap each other. For example, the first ends of the sixth semiconductor chip 146, the seventh semiconductor chip 147, and the eighth semiconductor chip 148 may be laterally offset from the first end of the semiconductor chip immediately therebelow toward the virtual central line VL. For example, the first ends of the fifth semiconductor chip 145, the sixth semiconductor chip 146, the seventh semiconductor chip 147, and the eighth semiconductor chip 148 of the upper stack US may be arranged in the form of uphill steps (e.g., a tiered structure) toward the virtual central line VL. In other words, the first side surfaces S1 of the fifth semiconductor chip 145, the sixth semiconductor chip 146, the seventh semiconductor chip 147, and the eighth semiconductor chip 148 of the upper stack US may be sequentially shifted at the same interval in an opposite direction to the first direction DR1. As a result, the heat source circuits 133 of the semiconductor chips 145 to 148 of the upper stack US may not vertically overlap each other.

In some implementations, the upper stack US and the lower stack LS may be arranged substantially point-symmetrical to each other on a plane.

In some implementations, the semiconductor chips 145 to 148 of the upper stack US and the package substrate 110 may be electrically connected to each other through the first conductive wires 137. For example, the first conductive wires 137 may be electrically connected to the chip pads of the semiconductor chips 145 to 148 of the upper stack US and the first substrate pad(s) 116. The semiconductor chips 141 to 144 of the lower stack LS and the package substrate 110 may be electrically connected to each other through the second conductive wires 139. For example, the second conductive wires 139 may be electrically connected to the chip pads of the semiconductor chips 141 to 144 of the lower stack LS and the second substrate pad(s) 118. In FIG. 5, the semiconductor chips 141 to 148 and the package substrate 110 may be electrically connected through the first conductive wires 137 and the second conductive wires 139. However, implementations of the present disclosure are not limited thereto. In some implementations, the semiconductor chips 141 to 148 and the base chip 120 may be also electrically connected to each other using the through-electrodes TSV and the chip terminals 136 of FIG. 2 or 3.

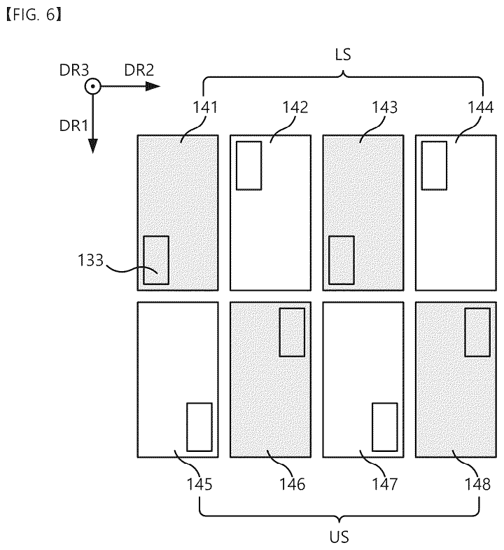

FIG. 6 is a plan view illustrating the semiconductor chips according to some implementations of the present disclosure. In detail, FIG. 6 is a plan view illustrating upper surfaces of the first to eighth semiconductor chips before stacking.

Referring to FIG. 6, for example, in each of the odd-numbered semiconductor chips (i.e., the first semiconductor chip 141 and the third semiconductor chip 143) of the lower stack LS, the heat source circuit 133 may be provided inside a corner area in which the left side and the lower side meet each other. In each of the even-numbered semiconductor chips (i.e., the second semiconductor chip 142 and the fourth semiconductor chip 144) of the lower stack LS, the heat source circuit 133 may be provided inside the corner area in which the left side and the upper side meet each other.

The upper stack US and the lower stack LS may be arranged substantially point-symmetrical to each other on a plane. For example, in each of the even-numbered semiconductor chips (i.e., the sixth semiconductor chip 146 and the eighth semiconductor chip 148) of the upper stack US, the heat source circuit 133 may be provided inside a corner area in which the right side and the upper side meet each other. In each of the odd-numbered semiconductor chips (i.e., the fifth semiconductor chip 145 and the seventh semiconductor chip 147) of the upper stack US, the heat source circuit 133 may be provided inside a corner area in which the right side and the lower side meet each other.

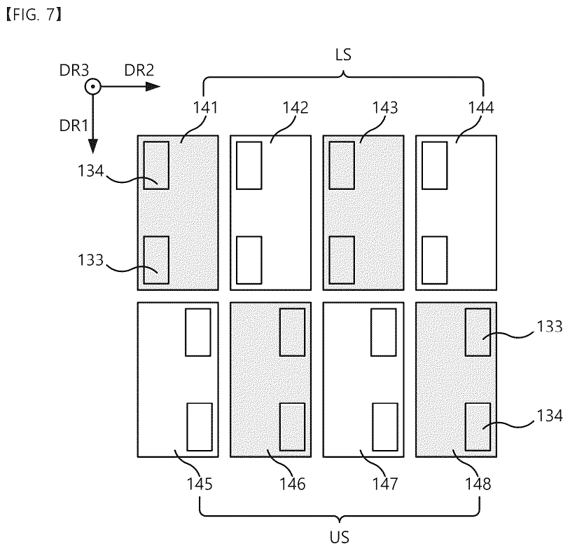

FIG. 7 is a plan view illustrating the semiconductor chips according to some implementations of the present disclosure. In detail, FIG. 7 is a plan view illustrating the upper surfaces of the semiconductor chips before stacking. Hereinafter, it is described that a first heat source circuit 133 and a second heat source circuit 134 are provided in each of the semiconductor chips 141 to 148, but this is merely exemplary, and the number of heat source circuits is not limited thereto.

Referring to FIG. 7, each of the semiconductor chips 141 to 148 may include the first heat source circuit 133 and the second heat source circuit 134. For example, in each of the semiconductor chips 141, 142, 143, and 144 of the lower stack LS, the first heat source circuit 133 may be provided inside a corner area in which the left side and the lower side meet each other, and the second heat source circuit 134 may be provided inside the corner area in which the left side and the upper side meet each other.

The upper stack US and the lower stack LS may be arranged substantially point-symmetrical to each other. For example, in each of the semiconductor chips 145, 146, 147, and 148 of the upper stack US, the first heat source circuit 133 may be provided inside the corner area in which the right side and the upper side meet each other, and the second heat source circuit 134 may be provided inside the corner area in which the right side and the lower side meet each other.

In some implementations, the odd-numbered semiconductor chips 141 and 143 of the lower stack LS and the even-numbered semiconductor chips 146 and 148 of the upper stack US may be the first type of semiconductor chips, and the even-numbered semiconductor chips 142 and 144 of the lower stack LS and the odd-numbered semiconductor chips 145 and 147 of the upper stack US may be the second type of semiconductor chips, which are different from the first type of semiconductor chips.

In some implementations, the first heat source circuit 133 and the second heat source circuit 134 may be operated alternately. For example, the first heat source circuit 133 and the second heat source circuit 134 of the first semiconductor chip 141 may be operated alternately. In other words, when the first heat source circuit 133 of the first semiconductor chip 141 is operated, the second heat source circuit 134 of the first semiconductor chip 141 may not be operated. In contrast, when the second heat source circuit 134 of the first semiconductor chip 141 is operated, the first heat source circuit 133 of the first semiconductor chip 141 may not be operated.

In addition, the first heat source circuits 133 (or the second heat source circuits 134) vertically adjacent to each other after stacking may also be operated alternately. For example, when the first heat source circuit 133 of the first semiconductor chip 141 is operated, the first heat source circuit 133 of the second semiconductor chip 142 may not be operated, and the second heat source circuit 134 of the second semiconductor chip 142 may be operated.

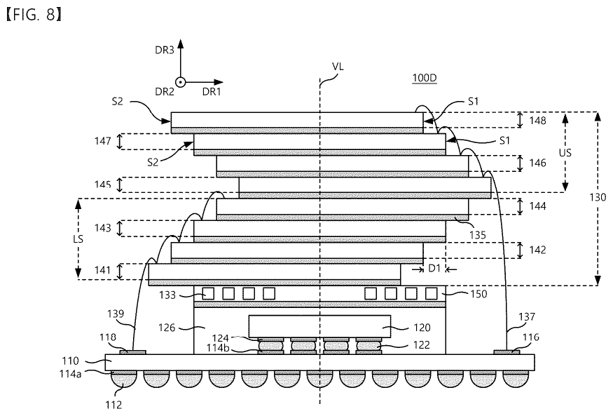

FIG. 8 is a cross-sectional view illustrating a semiconductor package according to some implementations of the present disclosure. Hereinafter, for convenience of description, differences from the above-described implementations will be mainly described.

Referring to FIG. 8, a semiconductor package 100D may further include a logic chip 150. Here, the logic chip 150 may be a semiconductor chip including the plurality of heat source circuits 133. In more detail, the logic chip 150 may be a semiconductor chip including the heat source circuits 133 electrically connected to the semiconductor chips 141 to 148, respectively. That is, the heat source circuits 133 required for the first to eighth semiconductor chips 141 to 148 may be provided inside the logic chip 150.

In some implementations, the logic chip 150 may be provided on the upper surface of the package substrate 110. For example, the logic chip 150 may be provided on the base chip 120, and the chip stack 130 may be provided on the logic chip 150. In other words, the logic chip 150 may be disposed between the base chip 120 and the chip stack 130.

In some implementations, the semiconductor chips 141 to 148 of the chip stack 130 may be the same type of semiconductor chips. In some implementations, the semiconductor chips 141 to 148 of the chip stack 130 may include the first type of semiconductor chips and the second type of semiconductor chips, which are different from the first type of semiconductor chips.

In some implementations, as illustrated in FIG. 8, the semiconductor chips 141 to 148, the logic chip 150, and the package substrate 110 may be electrically connected to each other through the conductive wires 137 and 139. Accordingly, the heat source circuits 133 of the logic chip 150 may be electrically connected through the conductive wires 137 and 139 and the package substrate 110. The semiconductor chips 141 to 148, the logic chip 150, and the base chip 120 may be electrically connected to each other through the package substrate 110. However, implementations of the present disclosure are not limited to a location of the logic chip 150 and/or the conductive wires 137 and 139 for connection between the chips of FIG. 8.

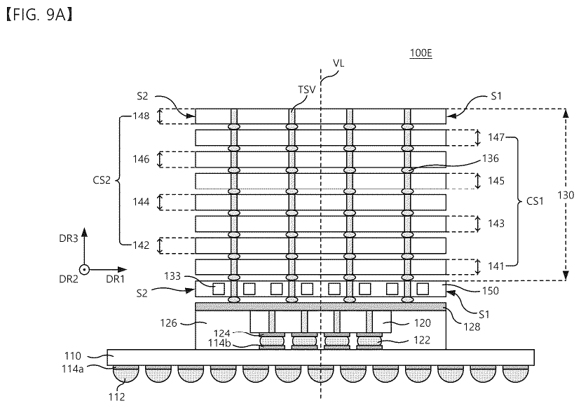

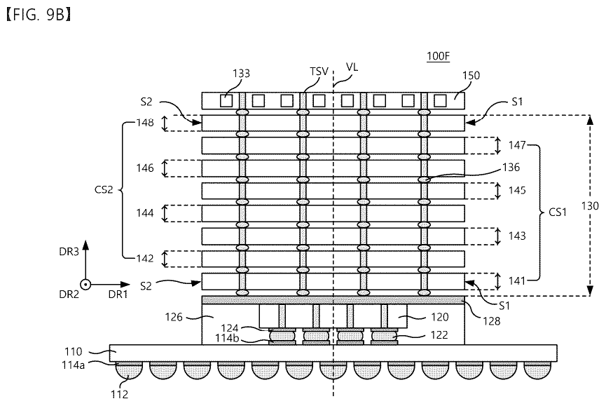

FIGS. 9A and 9B are cross-sectional views illustrating the semiconductor packages according to some implementations of the present disclosure. In detail, FIG. 9A is a cross-sectional view in which the logic chip 150 is disposed between the base chip 120 and the chip stack 130, and FIG. 9B is a cross-sectional view in which the logic chip 150 is disposed on the chip stack 130.

Referring to FIG. 9A, in a semiconductor package 100E, the logic chip 150 may be disposed between the base chip 120 and the chip stack 130. In other words, the logic chip 150 may be provided on an upper surface of the rewiring layer 128 and may be provided on the lower surface of the first semiconductor chip 141 (i.e., the lowermost semiconductor chip).

When the semiconductor chips 141 to 148 are connected to each other using the through-electrodes TSV and the chip terminals 136, the logic chip 150 may include the through-electrodes TSV. The through-electrodes TSV of the logic chip 150 may be electrically connected to the rewiring layer 128. The chip terminals 136 on the lower surfaces of the through-electrodes TSV of the first semiconductor chip 141 (i.e., the lowermost semiconductor chip) may be electrically connected to the logic chip 150. That is, the semiconductor chips 141 to 148 may be electrically connected to the base chip 120 through the logic chip 150.

Referring to FIG. 9B, in a semiconductor package 100F, the logic chip 150 may be disposed on an upper surface of the chip stack 130. In other words, the logic chip 150 may be provided on the upper surface of the eighth semiconductor chip 148 (i.e., an uppermost semiconductor chip).

When the semiconductor chips 141 to 148 are connected to each other using the through-electrodes TSV and the chip terminals 136, the logic chip 150 may include the through-electrodes TSV. The chip terminals 136 on the upper surface of the eighth semiconductor chip 148 (i.e., the uppermost semiconductor chip) may be electrically connected to the logic chip 150. That is, the logic chip 150 may be electrically connected to the base chip 120 through the semiconductor chips 141 to 148.

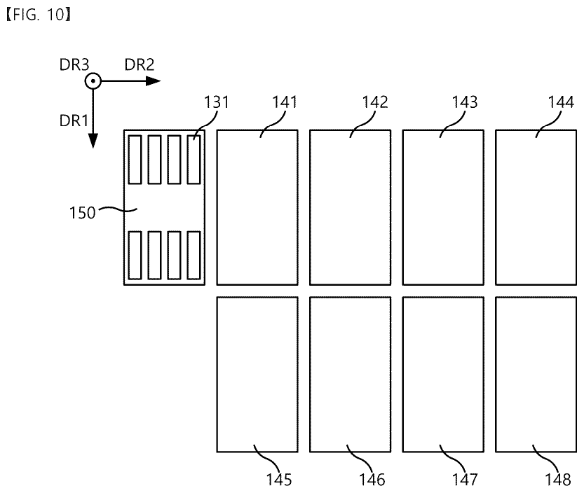

FIG. 10 is a plan view illustrating the semiconductor chips according to some implementations of the present disclosure. In detail, FIG. 10 is a plan view illustrating upper surfaces of the semiconductor chips 141 to 148 and the logic chip 150 before stacking.

Referring to FIG. 10, the logic chip 150 may include the heat source circuits 133 corresponding to the semiconductor chips 141 to 148. That is, the heat source circuits 133 required for the first to eighth semiconductor chips 141 to 148 may be provided inside the logic chip 150. Here, it is described that the heat source circuits 133 are provided on an upper side and a lower side of the logic chip 150, but this is merely exemplary, and the present disclosure is not limited thereto.

According to implementations of the present disclosure, accumulation of heat generated from semiconductor chips stacked in a semiconductor package may be reduced or minimized.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The above description is specific implementations for implementing the present disclosure. The present disclosure will include implementations of which a design may be simply changed or which may be easily changed in addition to the above-described implementations. The present disclosure will also include techniques that may be easily modified and implemented using the implementations. Thus, the scope of the present disclosure should not be limited to the above-described implementations, but should be determined by the appended claims, which will be described below, and equivalents to the appended claims of the present disclosure.

What is claimed is:

1. A semiconductor package comprising:
a package substrate; and
a chip stack on the package substrate, wherein the chip stack comprises a plurality of semiconductor chips,
wherein each semiconductor chip of the plurality of semiconductor chips includes:
a first side surface provided on one side of a virtual central line perpendicular to an upper surface of the package substrate and passing through a center of the chip stack; and
a second side surface provided on the other side of the virtual central line,
wherein odd-numbered semiconductor chips among the plurality of semiconductor chips include heat source circuits adjacent to the first side surfaces, and
wherein even-numbered semiconductor chips among the plurality of semiconductor chips include heat source circuits adjacent to the second side surfaces.

2. The semiconductor package of claim 1, wherein the plurality of semiconductor chips are the same type of semiconductor chip, and
wherein each of the even-numbered semiconductor chips and the odd-numbered semiconductor chips immediately therebelow nearer to the package substrate are point-symmetrical to each other about the virtual central line.

3. The semiconductor package of claim 1, wherein each of the odd-numbered semiconductor chips comprises a first end that includes the first side surface and the heat source circuit thereof and that is disposed on the one side of the virtual central line and comprises a second end that includes the second side surface thereof and that is disposed on the other side of the virtual central line,
wherein each of the even-numbered semiconductor chips comprises a first end that includes the first side surface thereof and that is disposed on the one side of the virtual central line and comprises a second end that includes the second side surface and the heat source circuit thereof and that is disposed on the other side of the virtual central line, and
wherein the first ends of the even-numbered semiconductor chips are laterally offset from the first ends of the odd-numbered semiconductor chips.

4. The semiconductor package of claim 3, wherein the first ends of the odd-numbered semiconductor chips are arranged in a tiered structure toward the virtual central line, and
wherein the second ends of the even-numbered semiconductor chips are arranged in a tiered structure toward the virtual central line.

5. The semiconductor package of claim 4, wherein the odd-numbered semiconductor chips and the package substrate are connected through first conductive wires, and
wherein the even-numbered semiconductor chips and the package substrate are connected through second conductive wires.

6. The semiconductor package of claim 3, wherein the first ends of the odd-numbered semiconductor chips vertically overlap each other, and
wherein the second ends of the even-numbered semiconductor chips vertically overlap each other.

7. The semiconductor package of claim 6, wherein the first side surfaces of the even-numbered semiconductor chips are laterally offset from the first side surfaces of the odd-numbered semiconductor chips by the same distance.

8. The semiconductor package of claim 2, wherein the first side surfaces of the odd-numbered semiconductor chips are vertically aligned with the first side surfaces of the even-numbered semiconductor chips.

9. The semiconductor package of claim 1, further comprising:
a base chip on the package substrate,
wherein the chip stack is on the base chip.

10. A semiconductor package comprising:
a package substrate;
a lower chip stack on the package substrate, the lower chip stack comprising a first plurality of semiconductor chips; and
an upper chip stack on the lower stack, the upper chip stack comprising a second plurality of semiconductor chips,
wherein each semiconductor chip of the lower chip stack and the upper chip stack includes
a first side surface provided on one side of a virtual central line perpendicular to an upper surface of the package substrate and passing through a center of the respective chip stack in which the semiconductor chip is positioned, and
a second side surface provided on the other side of the virtual central line,
wherein the second plurality of semiconductor chips of the upper chip stack include heat source circuits adjacent to the first side surfaces, and
wherein the first plurality of semiconductor chips of the lower chip stack include heat source circuits adjacent to the second side surfaces.

11. The semiconductor package of claim 10, wherein the first plurality of semiconductor chips of the lower chip stack include two or more different types of semiconductor chips,
wherein the two or more different types of semiconductor chips include a first type of semiconductor chip and a second type of semiconductor chip,
wherein each first type of semiconductor chip and each second type of semiconductor chip includes a first corner area and a second corner area adjacent to the second side surface and spaced apart from each other,
wherein the heat source circuit of each first type of semiconductor chip is provided in one of the first corner area or the second corner area,
wherein the heat source circuit of each second type of semiconductor chip is provided in the other one of the first corner area or the second corner area, and
wherein the upper chip stack and the lower chip stack are arranged substantially point-symmetrical to each other about the virtual central line.

12. The semiconductor package of claim 11, wherein odd-numbered semiconductor chips among the first plurality of semiconductor chips of the lower chip stack are the first type of semiconductor chips, and
wherein even-numbered semiconductor chips among the first plurality of semiconductor chips of the lower chip stack are the second type of semiconductor chips.

13. The semiconductor package of claim 11, wherein each semiconductor chip of the lower chip stack and the upper chip stack includes a first end disposed on the one side of the virtual central line and a second end disposed on the other side of the virtual central line,
wherein the first ends of the second plurality of semiconductor chips of the upper chip stack are laterally offset from each other, and
wherein the second ends of the first plurality of semiconductor chips of the lower chip stack are laterally offset from each other.

14. The semiconductor package of claim 13, wherein the first ends of the second plurality of semiconductor chips of the upper chip stack are arranged in a tiered structure toward the virtual central line, and
wherein the second ends of the first plurality of semiconductor chips of the lower chip stack are arranged in a tiered structure toward the virtual central line.

15. The semiconductor package of claim 14, wherein the second plurality of semiconductor chips of the upper chip stack and the package substrate are electrically connected through first conductive wires, and
wherein the first plurality of semiconductor chips of the lower chip stack and the package substrate are electrically connected through second conductive wires.

16. A semiconductor package comprising:
a package substrate;
a chip stack on the package substrate, wherein the chip stack includes a plurality of semiconductor chips; and
a logic chip on the package substrate and including heat source circuits electrically connected to the plurality of semiconductor chips of the chip stack.

17. The semiconductor package of claim 16, wherein the logic chip is between the chip stack and the package substrate.

18. The semiconductor package of claim 16, wherein the logic chip is on the chip stack, and the chip stack is between the logic chip and the package substrate.

19. The semiconductor package of claim 16, wherein the plurality of semiconductor chips comprise a same type of semiconductor chips.

20. The semiconductor package of claim 16, wherein each semiconductor chip of the chip stack does not include a heat source circuit.
